(19) United States
(12) Patent Application Publication
(10) Pub. No.: US 2010/0246609 A1
(43) Pub. Date: Sep. 30, 2010

(54) Semiconductor Lasing Device

(76) Inventors: Richard Phelan, Kilkenny (IE); John A. Patchell, Dublin (IE); James C. O'Gorman, Dublin (IE)

Correspondence Address: BROOKS, CAMERON & HUEBSCH , PLLC, 1221 NICOLLET AVENUE , SUITE 500, MINNEAPOLIS, MN, 55403, US

(21) Appl. No.: 12/223,106

(22) PCT Filed: Jan. 19, 2007
(86) PCT No.: PCT/EP2007/050561

§ 371 Date: Mar. 23, 2010

(30) Foreign Application Priority Data
Jan. 20, 2006 (EP) 06100689.6

(51) Int. Cl. H01S 5/065; H01S 3/30; H01S 5/10; H01L 21/04

(52) U.S. Cl. 372/4; 438/22; 372/45.01; 372/38.02; 372/34; 257/E21.04

(57) ABSTRACT

The present application provides a semiconductor Fabry-Perot dual mode lasing device having terahertz characteristics resulting in significant advantages over the prior art including for example operation at room temperatures and the absence of re-growth processing requirements.

### FIELD OF THE APPLICATION

The present application relates to laser devices and in particular to devices for producing terahertz radiation.

### BACKGROUND OF THE APPLICATION

Terahertz sources are used or have potential use in a variety of applications. For example, as terahertz radiation has the ability to penetrate deep into organic materials without the damage associated with ionizing radiation such as X-rays, it has application in the food industry for inspection in process and quality control. For similar reasons, they are employed in biomedical imaging. Terahertz sources are particularly desirable for medical imaging as they produce much less energy than x-rays and so are less stressful to biological tissue. It has also been suggested that a Terahertz radiation could be tuned to highlight specific types of tissue to detect, for example, early-stage skin cancer.

Terahertz lasers also have security applications. Scanners employing Terahertz lasers could penetrate clothing and plastics to detect hidden metal objects. Similarly, they could be employed in chemical detectors to identify toxic gases and explosives that have characteristic spectral fingerprints, or vibrations, in the terahertz region. Terahertz lasers may also be used for wireless communications.

Existing terahertz sources, including for example quantum cascade type lasers, suffer from a number of disadvantages including relatively high cost arising from complex manufacturing steps and the requirement for cryogenic operating temperatures.

### SUMMARY

The present application provides a terahertz lasing device that may be fabricated without undue complexity and which is suitable for operation at room temperature. In a first embodiment, a Fabry-Perot laser is provided having refractive index perturbations provided therein, wherein the index perturbations provide concurrent dual mode operation of the laser and where during dual mode operation of the laser, the two modes interact within the laser cavity to provide a beat frequency in the terahertz region. By dual mode operation is meant a situation in which two dominant modes exist. Thus whilst a lasing device may have a multitude of modes, two modes will be an order of magnitude or more greater than other modes. Suitably, a semiconductor lasing device is provided having a concurrent dual mode operation, where the dual modes coherently combine to provide a terahertz radiation device. The refractive index perturbations are suitably placed to define the dual mode operation characteristics. The wavelengths of the first and second modes of operation are suitably within the range from 800 nm to 1600 nm, and preferably within the range of 1250-1500 nm. Suitably, the difference in wavelength between the two modes of operation is selected to be less than 100 nm, preferably less than 20 nm. The reflectivity of the front lasing facet is selected to be above 10% and preferably above 50%. The reflectivity of the rear lasing facet is selected to be above 80% and preferably about 90%.

A further embodiment provides a terahertz region radiation producing device comprising

a semiconductor lasing device, and a control circuit for controlling the semiconductor device. Suitably, the control circuit is adapted to maintain the semiconductor device in a desired mode operation. The control circuit may adjust the drive current to the laser to maintain the semiconductor device in the desired mode of operation. A heat altering device may be provided for adjusting the temperature of the semiconductor lasing device. In which case, the control circuit may be configured to control the heat altering device to maintain the semiconductor in the desired mode of operation. The control circuit is suitably calibrated to maintain the lasing device in the desired mode of operation over a predefined external (ambient) temperature range. The heat altering device may comprise a heater, a cooler or a combination of the two. The cooler may be a Peltier device. The control circuit may include a temperature sensor for sensing the temperature of the laser. It will be appreciated that this combined heating and cooling technique may be used to extend the temperature range of a variety of semiconductor lasers and is not restricted, albeit particularly advantageous, to the dual mode terahertz devices of the present application.

Suitably, the dual mode lasing device suitably has an upper and a lower cladding layer, with a number of quantum wells provided there between, where the number of quantum wells is three or less. Advantageously, the number of quantum wells is limited to one.

Another embodiment provides an array comprising a plurality of dual mode lasing devices, where the characteristics of each individual dual mode device are selected to provide a different terahertz frequency. Having an array of such terahertz devices provides a discretely tunable terahertz device as different terahertz frequencies may be output from the different devices of the array.

Another embodiment comprises a method of manufacturing a semiconductor terahertz radiation device comprising the steps of: a) selecting a pattern of features suitable for providing a concurrent dual mode operating lasing device, and b) fabricating a semiconductor lasing device with the selected pattern of features. An additional step of testing the device may be included to ensure the lasing device has the required characteristics. A further step of providing a control device for operating the radiation device may be provided. The device may be tested to determine an optimum working point for terahertz radiation production. Once determined, the device may be set to operate at this determined optimum working point for a particular requirement. Suitably, the method of manufacture may comprise the step of applying highly reflective (e.g. greater than 50% on the front and greater than 80% on the rear) coatings on the lasing facets of the laser device. Suitably, the maximum gain of the device is substantially centred between the two fundamental frequencies of the device.

Another embodiment provides a semiconductor lasing device comprising two laser cavities, each laser cavity being adapted to operate in a single longitudinal mode, and a combiner for combining the modes of the two devices to provide a beat frequency in the terahertz range. The combiner may comprise a Multimode coupler or a Mach Zender interferometer. Suitably, the laser devices are ridge laser devices. Each ridge laser device may be patterned using a series of index perturbations such that each ridge laser device operates in a single longitudinal mode. Suitably, the difference in wavelength between the single longitudinal modes of the two devices is less that 30 nm.

These and other features, advantages and embodiments will become apparent from the description, which follows.

### BRIEF DESCRIPTION OF THE DRAWINGS

The present application will now be described with reference to the accompanying drawings in which:

FIG. 1 is a perspective view of a prior art design, which may be employed in the present application,

FIG. 2 is a profile view of the FIG. 1,

FIG. 3 is a the output from an exemplary device according to the application,

FIG. 4 is the temporal correlation of the output of the same device demonstrating terahertz radiation properties,

FIG. 5 is a representation of exemplary mirror loss and gain demonstrating required characteristics of devices according to the application,

FIG. 6 is an exemplary device according to the present application,

FIG. 7 is an array of devices according to the present application,

FIG. 8 is an exemplary device according to a further embodiment of the present application, and

FIG. 9 is an exemplary frequency spectrum showing the two dominant frequencies for the exemplary device of FIG. 8, and the resulting beat frequency in the teraHz region.

### DETAILED DESCRIPTION OF THE DRAWINGS

The present application employs semiconductor lasing devices where features are provided in the lasing structure to define the operating characteristics of the laser, i.e. index-patterned Fabry-Perot lasers. Conventional Fabry-Perot lasers are multi-mode devices that generally emit in a number discrete spectral lines determined by the separation of the cleaved facets of the laser crystal that comprise the laser resonator. Appropriately placed perturbations in the refractive index of the laser waveguide, provided for example by etching slots in the upper surface of the laser waveguide during the fabrication of the waveguide, can be used to make them lase in a selected or preferred single mode. Examples of such semiconductor lasing devices are the type referred to generally as a slotted laser, examples of slotted ridge lasers are described in EP 1214763, IES82521, WO2005006507 and WO03044871, the entire contents of which are herein incorporated by example. In a slotted laser, the slots are used to define the spectral characteristics of the device. Although, it will be appreciated that the application is not to be restricted to the use of slots and that other embedded features may be employed. In general terms, the perturbations may be caused by any index altering means which modifies the refractive index profile of the waveguide to an appropriate degree to manipulate optical feedback and hence the spectral content (output?) of the device. Thus whilst the perturbations may be defined by slots etched along the device other forms of perturbations (for example modifying the refractive index profile by employing doping or ion implantation methods) may also be employed.

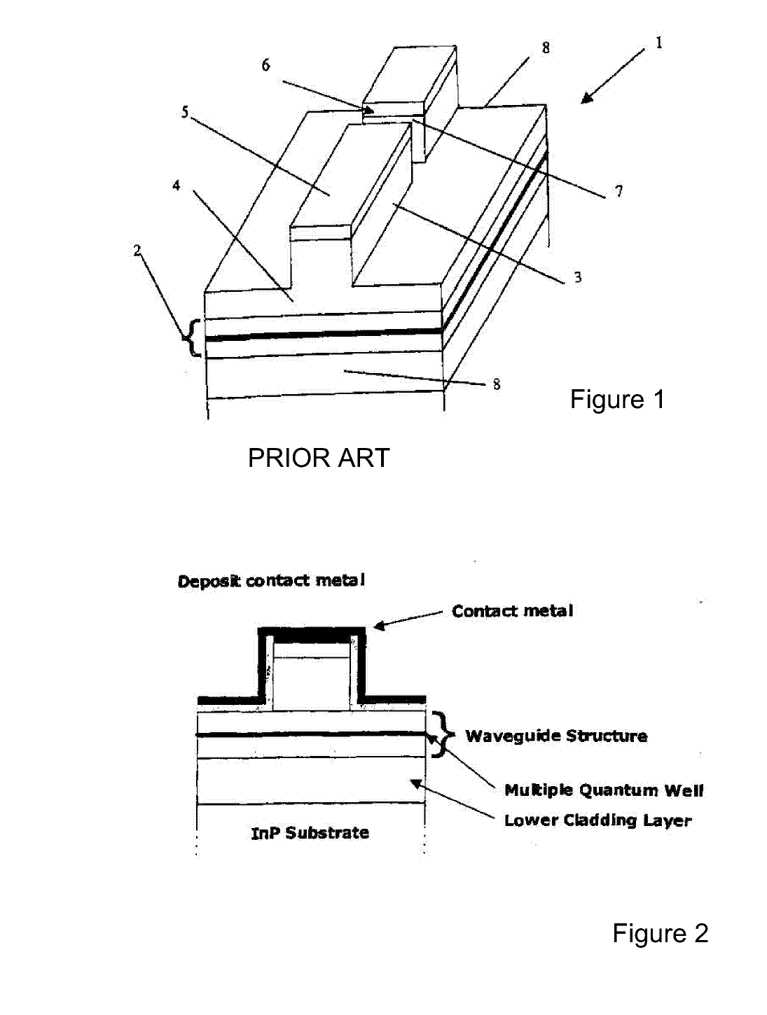

The term ‘slot length’ as used herein refers to the distance between the longitudinal slot faces in the device material, i.e. ‘slot length’ is measured along the direction of light propagation. Typically prior art slotted laser devices, as shown in FIGS. 1 and 2, comprise a number of waveguiding layers 2 (containing for example a multiple quantum well structure) covered by an upper cladding layer 4. Primary optical feedback means are provided in the form of a cleaved facet 8 at either end of the device. The distance between the facets determines the exact wavelengths of the Fabry Perot modes of the cavity. The upper cladding layer 4 forms a ridge 3 having a cap layer 5. Beneath the upper cladding layers are one or more cladding layers 8 and the substrate. The slot features in such known devices are formed by etching a slot 6 in the ridge waveguide, resulting in two longitudinal interfaces 7 that are perpendicular to the direction of light propagation within the device. WO05006507 discusses the mechanism whereby slotted lasers achieve their single mode performance and provides a particularly advantageous method for achieving this and in particular the use of perturbations having only one interface contributing to optical feedback along the optical path. This single interface slot is of particular particularly suitable for devices in accordance with the present application, as the parameters of the device may be predictably selected.

Whilst heretofore, these methods have been employed with the intention of providing improved single mode lasers, they may be readily employed to design and manufacture a dual mode laser (conventionally multi-mode lasers have been viewed as undesirable with specific interest directed to single mode lasers), the purpose of which will be discussed below. For example a genetic design algorithm technique may be employed to identify a particular perturbation pattern, which may be used to achieve a desired frequency response in the terahertz region of the spectrum. In particular, the devices of the present application are capable of providing a terahertz radiation source providing terahertz radiation having a frequency between 0.05 and 100 terahertz.

The present application seeks to employ a dual mode laser in which the laser device has two modes of operation rather than one, i.e. there are two fundamental frequencies produced by the laser. Moreover, the present application employs the results of the interaction between the two modes to produce terahertz radiation. This interaction is believed to be the result of four-wave mixing. In simple terms, a beat frequency is produced corresponding to the difference in frequency between the two fundamental frequencies of the laser.

Whilst dual mode featured laser devices are known, they have to date largely been ignored as unwanted by-products of the single mode laser manufacturing process (i.e. faulty products). Moreover, the operating characteristics of these dual mode devices is such that one mode or the other tends to dominate at any particular operating point.

The present application results from the realisation that the dual mode operation may be usefully employed in circumstances where the two frequencies may be made to interact coherently and more particularly, where the interaction may be employed to produce terahertz radiation. The present application employs a semiconductor lasing device having a dual mode operation, where the dual modes constructively combine to provide a terahertz radiation device.

Achieving a useful interaction between the two frequencies is not straightforward. A reason for this is that generally one mode will be dominant over the other mode. If the dominance is too much the interaction will not produce the required result. To complicate matters, the dominance may shift from one mode to the other as the operating characteristics, for example operating temperature or current change.

To provide a terahertz device, features are selected to specifically provide at least dual mode operating characteristics (the opposite of what is conventionally sought in such lasing devices). The theory behind the technique of feature selection is known (e.g. WO05006507). However, heretofore it has been employed to achieve good single mode performance. The theory and techniques may however be readily adapted to ensure required dual mode operation. It will be appreciated that the specific features, cavity lengths etc will depend on the particular design.

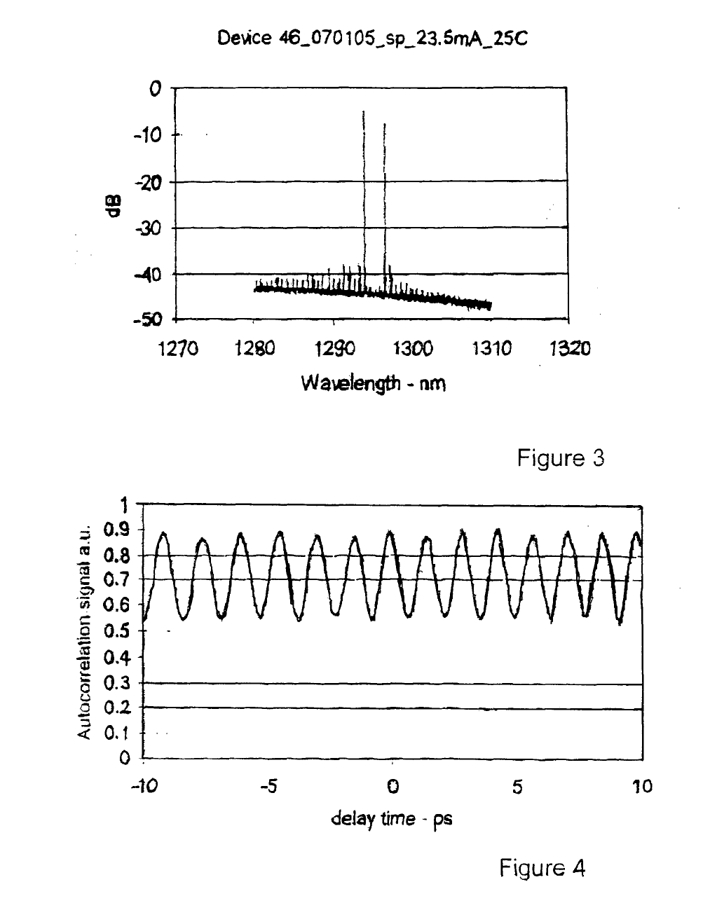

Once these techniques are employed, a semiconductor lasing device may be selected having a concurrent dual mode operation, as shown from the exemplary results of one design, shown in FIG. 3. In contrast to prior art devices, the two modes (frequencies) are concurrently provided. The intensity of each mode is similar in amplitude compared to other modes of the device. Moreover, as will be appreciated from the results shown in FIG. 4 for this device, the intensity correlation figures shown in FIG. 4 demonstrate the production of terahertz oscillation in the laser emission and the associated production of terahertz radiation by virtue of the resultant oscillation of the charge density in the laser.

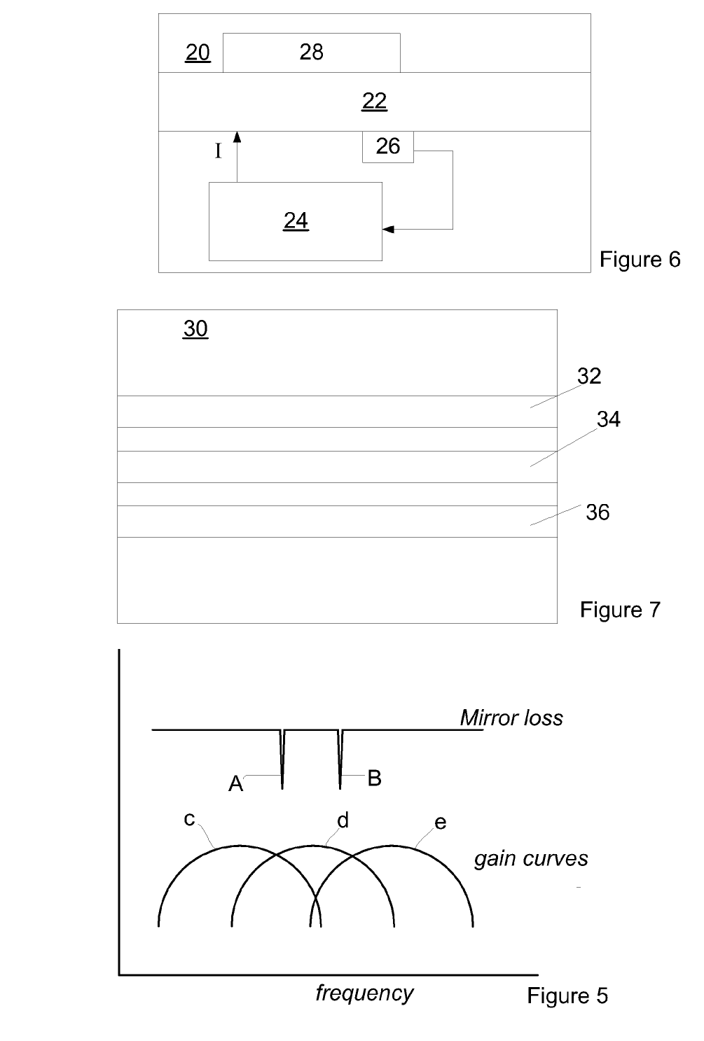

In contrast to other designs, the semiconductor lasing device of the present application specifically employs perturbations to provide the dual modes. In order to ensure that the two modes operate concurrently, it is necessary to consider two criteria. The first is the mirror loss spectrum for the device and the second is the modal gain of the device. Whilst a device may be designed to have a particular mirror loss spectrum for dual mode activity, e.g. as shown in the theoretical representation of FIG. 5 where two modes A and B are shown, if this does not substantially coincide with the modal gain of the laser the output will be single rather than the required dual mode. Thus for example, if the exemplary gain curve c is used, A will be the dominant mode and B will be suppressed. Whereas, if E is the gain curve, the dominant mode will be B and A will be suppressed. The gain curve d, which is centred between the two modes, ensures that both modes operate concurrently. It will be appreciated that the two modes need not be identical in amplitude so long as they each are dominant with respect to the other frequencies. Moreover, it is not essential that the gain be equally applied to both modes or that both modes have the same mirror loss, since gain may be used to compensate inadequate mirror loss and vice versa.

The two modes of the lasing device are selected to be in the range of 800 nm to 1600 nm and more preferably in the range 1250-1500 nm. Whilst the length of the lasing cavity structure may be, for example, selected to be about 350 microns. However, a longer cavity may be required for providing a laser with closer Fabry-Perot modes and thus a device that may be tuned (using slots or other perturbations) to produce dual modes closer in frequency and hence lower terahertz radiation. The difference in wavelength between the two modes of operation is selected to be less than 100 nm and preferably less than 20 nm.

In contrast to conventional devices, it is believed that high reflectivity coatings on the facet can considerably contribute to improved performance. Suitably, the reflectivity of the front lasing-light emitting facet is selected to be above 10% and preferably above 50%. The reflectivity of the rear lasing facet is selected to be above 80% and preferably about 90%. In some configurations the laser may work best with high reflectivity coatings on both facets to ensure that most of the energy pumped into the laser as electric current comes out in the terahertz regime as opposed to as light, i.e. the use of high reflectivity coatings on both facets will lead to more efficient terahertz radiation generation.

As explained above, the appropriate gain is required for the operation of the device. However, the gain in a semiconductor is not constant and varies with temperature and current. Accordingly, the dual mode nature of the devices may have a narrow operating range. To ensure consistent operation and to provide a wider operating range, a further embodiment provides a radiation producing device which comprises the previously discussed dual mode semiconductor laser device 20 and additionally comprises a control circuit for controlling the semiconductor device. In particular, the control circuit is adapted to maintain the semiconductor device in dual mode operation. The control circuit provides the driving current for the laser. The control circuit operates is such a manner to ensure that the gain does not change significantly. As laser gain varies with current, the control circuit may be adapted to maintain a constant drive current to the laser. Moreover as gain is responsive to temperature, the control circuit may incorporate a temperature sensor measuring the temperature of the laser, either directly or indirectly. The control circuit may be configured to alter the drive current (and thus the gain) in response to a change in temperature. However, it will be appreciated that this would in turn affect the power output of the device.

An alternative is to employ a heat altering device 28 to maintain the temperature of the semiconductor lasing device within the temperature range permitting dual mode operation.

In one arrangement, the heat altering device is a heating device, e.g. a resistance incorporated into the same semiconductor as the lasing device. In such an arrangement, the normal operating temperature of the laser is selected to be relatively high, so that in low ambient temperatures the heater is used to raise the temperature of the laser for correct operation, whereas at higher ambient temperatures the heater is not employed. In temperatures in between, the heater may be partially employed.

In another arrangement, the heat altering device is a cooling device, e.g. a Peltier-type device which may be mounted to the base of the laser substrate, incorporated into the same semiconductor as the lasing device. In this arrangement, the normal operating temperature of the laser is selected to be relatively low, so that in low ambient temperatures the cooling device is not required but as the temperature increases, the cooling device is not employed to reduce the temperature of the lasing device. It will be appreciated that both a heating and a cooling device may be employed to ensure operation over an extended range.

To ensure correct operation of the device, the device may initially be calibrated to determine its optimum working temperature or temperature range. These values may be stored (e.g. in a memory) or set (e.g. by means of an external resistor or a gate array) in the control circuit. Similarly, the device may be calibrated for different drive currents. So that for any given drive current, the required operating temperature is known, which may be maintained by the control of the heat altering device.

A further embodiment, shown in FIG. 7, provides an array comprising a plurality of dual mode lasing devices (32,34,36) fabricated together on the same substrate 30. Suitably, each device is selected to provide a different terahertz frequency. In this way a discretely tunable terahertz frequency radiation device may be provided, where each laser may be selectively switched on or off.

To manufacture a device of the type described above requires two main steps. The first step employs the previously described methods to select (design) a pattern of features suitable for providing a concurrent dual mode operating lasing device. The second step is the fabrication of the semiconductor lasing device with the selected pattern of features. Methods for fabricating semiconductor lasers are well known in the art. In constructing the device, it may be advantageous to provide a device with a relatively flat gain curve as this enables wider separation frequencies between the two modes and hence higher terahertz frequencies. Also with flatter gains, the effects of temperature and current on the temperature range may be reduced. One method of flattening the gain is to reduce the number of quantum wells employed. Thus whilst a conventional device may have five or more quantum wells, a flatter gain curve may be achieved with three or less and preferably just one quantum well. In addition, careful selection of high reflectivity coatings may enhance the device characteristics.

After manufacture, the devices may be tested to ensure they have the required characteristics. As described above, this step of testing the device may include determining the optimum working temperature or range of the device.

The above exemplary embodiments have employed a single laser cavity to concurrently produce a dual mode laser. An alternative embodiment will now be described in which the dual modes are generated in different laser cavities and then combined to produce a beat frequency in the teraHz range.

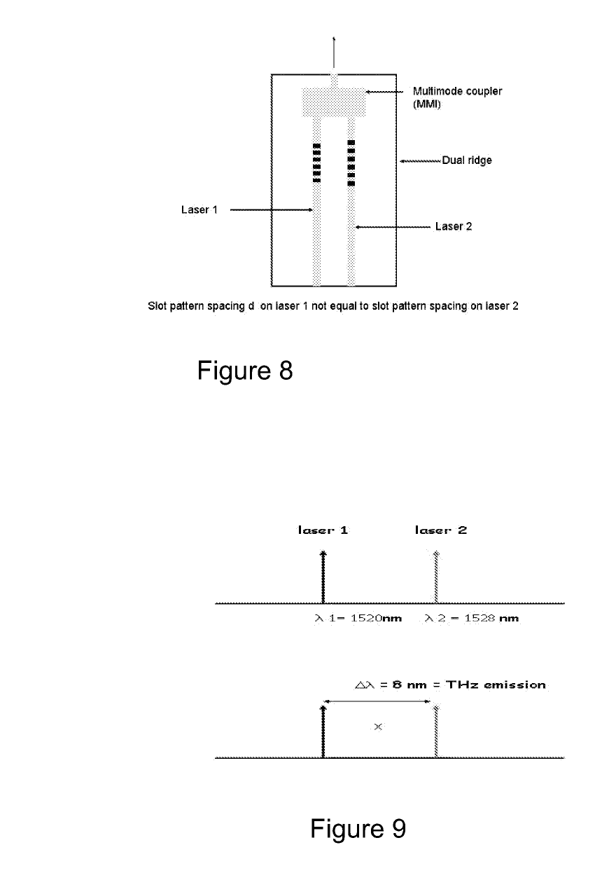

In particular, a semiconductor laser device is provided, as illustrated in FIG. 8, comprising two separate ridge laser devices (slotted laser devices). The two laser devices are advantageously fabricated on the same substrate. The two devices are positioned adjacent to one and other. A first pattern of refractive index perturbations (slot pattern) is provided on the first laser device. The first pattern is selected to ensure the first laser device emits a single longitudinal mode, and in particular produces a first wavelength of light λ₁ corresponding to a first frequency f₁ as shown in FIG. 9. A second pattern of refractive index perturbations is provided on the second laser device. The second pattern is selected to produce light of a second wavelength λ₂ corresponding to a second frequency f₂. Depending on the desired terahertz frequency, the difference in wavelength λ between the two modes may be selected to be in the range from just above 0 nm to 30 nm. A combiner, for example a Multimode coupler (MMI) or Mach-Zender interferometer, is positioned to receive the light from the facets of each of the two lasers. The two wavelengths combine within the combiner to produce a beat frequency in the teraHertz range. The benefit of this arrangement is that an increased power of THz emission as there is less absorbtion of THz since the combiner length is smaller than that of the laser cavity.

It will be appreciated that using index-patterned Fabry-Perot lasers to produce dual mode lasers for terahertz applications have significant advantages over the prior art including for example operation at room temperatures and the absence of re-growth processing requirements.

The words comprises/comprising when used in this specification are to specify the presence of stated features, integers, steps or components but does not preclude the presence or addition of one or more other features, integers, steps, components or groups thereof.

1.-50. (canceled)

51. A semiconductor lasing device adapted to have concurrent dual mode operation, where the dual modes coherently combine to provide a terahertz radiation device.

52. A semiconductor lasing device according to claim 51, where suitably placed refractive index perturbations are employed to define the dual mode.

53. A semiconductor lasing device according to claim 51 where the wavelength of the first mode of operation is in the range 800 nm to 1600 nm.

54. A semiconductor lasing device according to claim 53, where the wavelength of the first mode of operation is in the range 1250-1500 nm.

55. A semiconductor lasing device according to claim 53 where the wavelength of the second mode of operation is in the range 800 nm to 1600 nm.

56. A semiconductor lasing device according to claim 55, where the wavelength of the second mode of operation is in the range 1250-1500 nm.

57. A semiconductor lasing device according to claim 51, wherein the difference in wavelength between the two modes of operation is selected to be less than 100 nm.

58. A semiconductor lasing device according to claim 51, wherein the difference in wavelength between the two modes of operation is selected to be less than 20 nm.

59. A semiconductor lasing device according to claim 51 wherein the reflectivity of the front lasing facet is selected to be above 10% and preferably above 50%.

60. A semiconductor lasing device according to claim 59 wherein the reflectivity of the rear lasing facet is selected to be above 80% and preferably about 90%.

61. A radiation producing device comprising:
a semiconductor lasing device according to claim 51, and
a control circuit for controlling the semiconductor device.

62. A device according to claim 61, wherein the control circuit is adapted to maintain the semiconductor device in dual mode operation.

63. A device according to claim 62, wherein the control circuit is adapted to adjust the current to maintain the semiconductor device in concurrent dual mode operation.

64. A device according to claim 61, further comprising a heat altering device for adjusting the temperature of the semiconductor lasing device.

65. A device according to claim 64, wherein the control circuit is configured to control the heat altering device to maintain the semiconductor in dual mode operation.

66. A device according to claim 64, wherein the heat altering device comprises a heater.

67. A device according to claim 64, wherein the heat altering device comprises a cooler.

68. A device according to claim 67, wherein the cooler is a Peltier device.

69. An array comprising a plurality of devices according to claim 51, where the characteristics of each device is selected to provide a different terahertz frequency.

70. A method of manufacturing a semiconductor terahertz radiation device comprising the steps of:
a) selecting a pattern of features suitable for providing a concurrent dual mode operating lasing device, and
b) fabricating a semiconductor lasing device with the selected pattern of features.
